(19) United States
(12) Patent Application Publication
(10) Pub. No.: US 2008/0261497 A1
(43) Pub. Date: Oct. 23, 2008

(54) Retainer Ring For Cmp Device

(76) Inventor: Tsutomu Ichinoshime, Kanagawa (JP)

Correspondence Address: ARENT FOX LLP, 1050 CONNECTICUT AVENUE, N.W., SUITE 400, WASHINGTON, DC, 20036, US

(21) Appl. No.: 12/096,512

(22) PCT Filed: Mar. 2, 2006
(86) PCT No.: PCT/JP2006/303958

§ 371 Date: Jun. 6, 2008

(30) Foreign Application Priority Data
Aug. 12, 2005 (JP) 2005-354261

(51) Int. Cl. B24B 41/06; H01L 21/304; B24B 5/00

(52) U.S. Cl. 451/285; 451/289

(57) ABSTRACT

A two-layer structure retainer ring is capable of giving a uniform pressing force while uniting a first ring and a second ring more securely. A first ring 11 is formed with a pressed-and-fitted portion 11d over the full circumference of a lower surface 11c thereof and a second ring 12 is formed with a pressing-and-fitting portion 12d over the full circumference of an upper surface 12c thereof; the first ring 11 and the second ring 12 are united by pressing and fitting the pressing-and-fitting portion 12d into the pressed-and-fitted portion 11d; and an adhesive 13 is provided between the lower surface 11c of the first ring 11 and the upper surface 12c of the second ring 12.

### TECHNICAL FIELD

The present invention relates to a retainer ring provided in (attached to) a holding head of a CMP (or chemical mechanical polishing) apparatus polishing a wafer (polished body) chemically and mechanically, particularly, a retainer ring having a two-layer structure of a first ring and a second ring.

### BACKGROUND ART

As a semiconductor device has more highly integrated and has performed better, the measurements in the horizontal directions (on the plane) have shortened and the structure thereof in the vertical directions has been fined down and multi-layered. In order to realize such a fine and multi-layered structure, a semiconductor substrate (such as a silicon substrate) needs to have a high flatness (evenness). Hence, the flatness has to be heightened at the stage of a wafer, and in response to this demand, a CMP Apparatus is used.

This CMP Apparatus is configured by, for example: a rotary base; a polish pad disposed on this base; and a holding head which holds a wafer and presses it against the polish pad; a slurry supply nozzle; and the like. The holding head is formed by: a retainer ring which surrounds the periphery of the wafer; for example, an elastic film which presses the upper surface of the wafer; an air chamber which is enclosed with this elastic film, the retainer ring and a head body; an air supply path which supplies air for pressurization into this air chamber. The retainer ring surrounds the periphery of the wafer and prevents the wafer from popping out. It also presses the polish surface of the polish pad, and flattens and fines down (suits) the polish surface of the polish pad which polishes the wafer.

Such a retainer ring has, for example, a two-layer structure (two-piece structure) of a first ring made of metal and a second ring made of engineering plastic. The metallic first ring reinforces the engineering-plastic second ring, thereby making the whole retainer ring more rigid. Two types of retainer rings are known including two rings united (joined) by bolting and united with an adhesive (bonding agent).

A bolting-type retainer ring includes, as shown in FIG. 12, a first ring 100 formed with a plurality of bolt insertion holes 100a and a second ring 101 formed with a plurality of screw holes 101a (internal threads) in positions corresponding to the bolt insertion holes 100a. The two first ring 100 and second ring 101 are united by placing one on top of the other, inserting a bolt 102 into each bolt insertion hole 100a and tightening (screwing) it into a corresponding screw hole 100a (e.g., refer to Patent Document 1). On the other hand, an adhesive-type retainer ring includes, as shown in FIG. 13, a first ring 110 and a second ring 111 united by applying an adhesive to a lower surface 110a of the first ring 110 and an upper surface 111a of the second ring 111, superimposing one on the other and pressurizing them. Both the first ring 100 of the bolting-type retainer ring and the first ring 110 of the adhesive-type retainer ring are formed with a plurality of screw holes for attaching them to a holding head.

### Patent Document 1: Japanese Patent Laid-Open Publication No. 2005-34959

### DISCLOSURE OF THE INVENTION

### Problems to be Solved by the Invention

In such a bolting-type retainer ring, however, a vibration, a repeated stress (e.g., a compressive stress and a shearing stress) or the like caused by polishing a wafer may loosen some bolts to thereby become uneven in flatness of a second ring and pressing force against a polish pad by the retainer ring. Besides, all the bolts are not necessarily uniformly loosened, thereby making the pressing force of the retainer ring further uneven and unstable. Further, the formation of a plurality of holes in a first ring and a second ring produces a difference in pressing force between a pressure surface (lower surface of the second ring for pressing a polish surface of a polish pad) under the holes and a pressure surface in the other part (produces an uneven pressure surface). Still further, some slight difference in bolting force may affect the flatness of a pressure surface or deflect a second ring to unbalance the pressing force, thereby making it impossible to polish a wafer with an extremely high precision (flatness or the like).

On the other hand, in an adhesive-type retainer ring, wafer polishing may give the retainer ring to a shearing stress or the like to thereby peel off a first ring and a second ring. This is facilitated by slurry (abrasive), polish chips or the like coming between the first ring and the second ring. Besides, adhesives are difficult to perfectly uniformly mix or apply, and thus, uneven adhesive mixing or applying causes the first ring and the second ring to peel off, or makes the unification (adhesion) of the first ring and the second ring unstable.

Therefore, it is an object of the present invention to provide a two-layer structure retainer ring capable of giving a uniform pressing force while uniting a first ring and a second ring more securely.

### Means for Solving the Problems

In order to accomplish the object, a retainer ring according to claim 1 which has a two-layer structure of a first ring and a second ring in a holding head of a CMP apparatus is characterized in that the first ring and the second ring are united by at least either of a pressing-in means and a fitting means.

A retainer ring according to claim 2 is characterized in that, in the retainer ring according to claim 1, the pressing-in means includes a pressing portion formed in a lower part of the first ring and a pressed portion to be pressed by the pressing portion formed in an upper part of the second ring.

A retainer ring according to claim 3 is characterized in that, in the retainer ring according to claim 2, the pressing portion is formed over the full circumference in a lower part of the first ring, and the pressed portion is formed over the full circumference in an upper part of the second ring.

A retainer ring according to claim 4 is characterized in that, in the retainer ring according to claim 1, the pressing-in means includes a pressed portion formed in a lower part of the first ring and a pressing portion to press the pressed portion formed in an upper part of the second ring.

A retainer ring according to claim 5 is characterized in that, in the retainer ring according to claim 4, the pressed portion is formed over the full circumference in a lower part of the first ring, and the pressing portion is formed over the full circumference in an upper part of the second ring.

A retainer ring according to claim 6 is characterized in that, in the retainer ring according to claim 1, the fitting means includes a fitting portion formed in a lower part of the first ring and a fitted portion to be fitted by the fitting portion formed in an upper part of the second ring.

A retainer ring according to claim 7 is characterized in that, in the retainer ring according to claim 6, the fitting portion is formed over the full circumference in a lower part of the first ring, and the fitted portion is formed over the full circumference in an upper part of the second ring.

A retainer ring according to claim 8 is characterized in that, in the retainer ring according to claim 1, the fitting means includes a fitted portion formed in a lower part of the first ring and a fitting portion to fit the fitted portion formed in an upper part of the second ring.

A retainer ring according to claim 9 is characterized in that, in the retainer ring according to claim 8, the fitted portion is formed over the full circumference in a lower part of the first ring, and the fitting portion is formed over the full circumference in an upper part of the second ring.

A retainer ring according to claim 10 is characterized in that, in the retainer ring according to any one of claims 1 to 9, a bonding agent is provided between the first ring and the second ring.

A retainer ring according to claim 11 is characterized in that, in the retainer ring according to any one of claims 1 to 10, the first ring is metallic and the second ring is super-engineering plastic.

### ADVANTAGES OF THE INVENTION

In the retainer ring according to claim 1, the first ring and the second ring are united by at least either of a pressing-in means and a fitting means, thereby keeping them more securely united. In the pressing-in and fitting unification, a vibration, a repeated stress or the like given to the retainer ring by polishing a wafer is prevented from loosening the press-in or fitting state, thereby keeping the first ring and the second ring more securely united. In addition, slurry, polish chips or the like is hindered from coming into the press-in or fitting part, and even if it comes accidentally into there, then slurry, polish chips or the like will not loosen the press-in or fitting to thereby keep the retainer ring more securely united. Besides, the securer press-in or fitting maintains the flatness of the retainer ring to thereby unify the pressing force against a polish pad and keep the uniformity unchanged.

In the retainer ring according to claim 2 or 4, the pressing portion is pressed into the pressed portion, thereby uniting the first ring and the second ring and keeping the rings more securely united.

In the retainer ring according to claim 3 or 5, the pressing portion and the pressed portion are formed over the full circumference of the ring, thereby realizing a press-in of the pressing portion and the pressed portion over the full circumference of the ring, and thus, keeping the ring still more securely united. Besides, the formation of the pressing portion and the pressed portion over the full circumference of the ring unifies the shape or unification state (press-in state) of the ring over the whole circumference, thereby making uniform the pressing force against the polish pad.

In the retainer ring according to claim 6 or 8, the fitting portion fits with the fitted portion, thereby uniting the first ring and the second ring and keeping the rings more securely united.

In the retainer ring according to claim 7 or 9, the fitting portion and the fitted portion are formed over the full circumference of the ring, thereby realizing fitting of the fitting portion and the fitted portion over the full circumference of the ring, and thus, keeping the rings still more securely united. Besides, the formation of the fitting portion and the fitted portion over the full circumference of the ring unifies the shape or unification state (fitting state) of the ring over the whole circumference, thereby making uniform the pressing force against the polish pad.

In the retainer ring according to claim 10, the bonding agent is provided between the first ring and the second ring, thereby keeping the first ring and the second ring more securely united. Besides, the bonding agent prevents slurry, polish chips or the like from coming into the joint part, thereby further stabilizing the united ring.

In the retainer ring according to claim 11, the metallic first ring and the super-engineering plastic second ring are united by at least either of the pressing-in means and the fitting means, thereby preventing some difference in material, strength or the like between the first ring and the second ring from deforming or distorting them, so that the two rings can be well united.

### BRIEF DESCRIPTION OF THE DRAWINGS

FIG. 1 is a schematic front view showing a configuration of a CMP apparatus according to an embodiment of the present invention.

FIG. 2 is a schematic sectional view of a holding head of the CMP apparatus according to the embodiment of the present invention.

FIG. 3(a) is a plan view of a first ring in a retainer ring according to the embodiment of the present invention, and FIG. 3(b) is a sectional view along an A-A line of the first ring.

FIG. 4(a) is a plan view of a second ring in the retainer ring according to the embodiment of the present invention, and FIG. 4(b) is a sectional view along a B-B line of the second ring.

FIG. 5 is a sectional view showing the first ring and the second ring united in the retainer ring according to the embodiment of the present invention.

FIG. 6 is a sectional view showing a first ring and a second ring united in a second retainer ring according to the embodiment of the present invention.

FIG. 7 is a sectional view showing a first ring and a second ring united in a third retainer ring according to the embodiment of the present invention.

FIG. 8 is a sectional view showing a first ring and a second ring united in a fourth retainer ring according to the embodiment of the present invention.

FIG. 9 is a sectional view showing a first ring and a second ring united in a fifth retainer ring according to the embodiment of the present invention.

FIG. 10 is a sectional view showing a first ring and a second ring united in a sixth retainer ring according to the embodiment of the present invention.

FIG. 11 is a sectional view showing a first ring and a second ring united in another retainer ring according to the embodiment of the present invention.

FIG. 12(a) is a perspective view showing a conventional retainer ring including a first ring and a second ring united by bolting, and FIG. 12(b) is a sectional view along a C-C line of the retainer ring.

FIG. 13 is a perspective view showing a conventional retainer ring including a first ring and a second ring united with an adhesive.

### BEST MODE FOR CARRYING OUT THE INVENTION

An embodiment of the present invention will be below described with reference to the drawings.

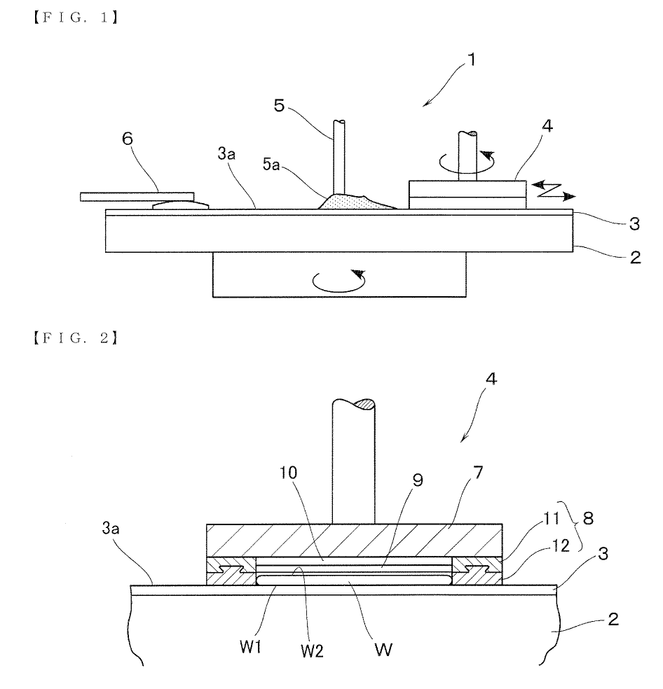

FIG. 1 is a schematic front view showing a configuration of a CMP apparatus 1 according to the embodiment of the present invention. The CMP apparatus 1 has a configuration equivalent to a widely-used CMP apparatus, apart from a retainer ring 8 (described later). In this embodiment, it includes a rotary base 2, a polish pad 3 (such as a cloth) disposed on the base 2, a holding head 4, a slurry supply nozzle 5 and a dresser 6 (dressing means), though no detailed description is given here. The CMP apparatus 1 polishes a wafer W chemically and mechanically.

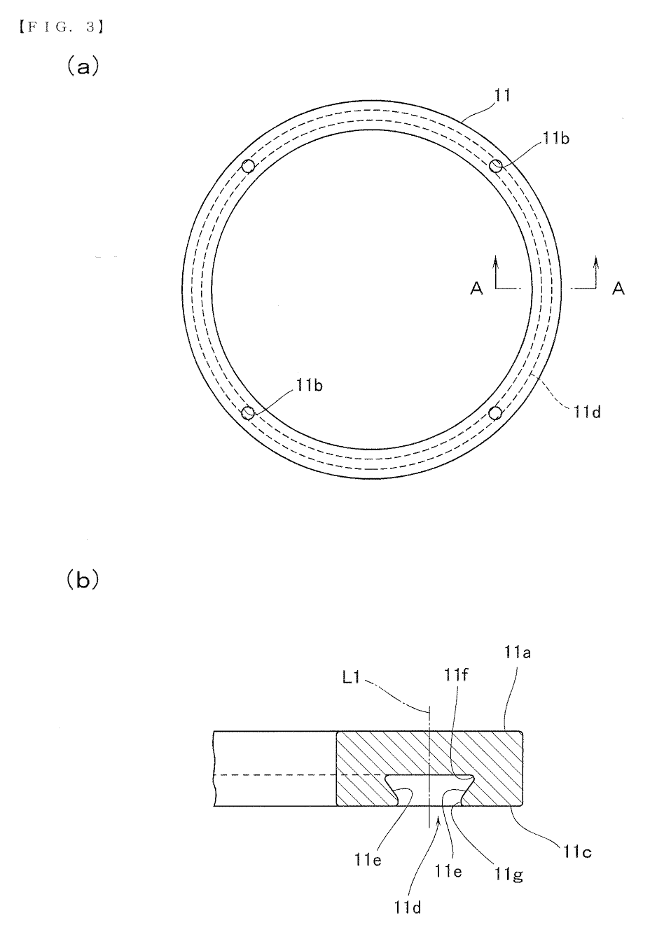

The holding head 4 holds the wafer W and presses a polished surface W1 against the polish pad 3. It is designed to move on the polish pad 3 while rotating. In this embodiment, the holding head 4 is, as shown in FIG. 2, provided with a head body 7, the retainer ring 8 disposed under the head body 7 and an elastic film 9 which is located inside of the retainer ring 8 and presses an upper surface W2 of the wafer W. Air for pressurization is supplied into an air chamber 10 enclosed with the head body 7, the retainer ring 8 and the elastic film 9 to thereby press the wafer W against the polish pad 3 via the elastic film 9.

The retainer ring 8 has a ring shape, surrounds the periphery of the wafer W, prevents the wafer W from popping out of the holding head 4 and presses a polish surface 3a of the polish pad 3 to thereby flatten and fine down (suits) the polish surface 3a (the part which comes into surface contact with the polished surface W1 of the wafer W) of the polish pad 3 which polishes the wafer W. Specifically, the retainer ring 8 flattens and fines down the surface of the polish surface 3a of the polish pad 3 having a low flatness and a great surface roughness due to slurry 5a (abrasive). The retainer ring 8 has a two-layer structure formed by placing a first ring 11 made of stainless steel (e.g., SUS304 and SUS316) on top of a second ring 12 made of super-engineering plastic (e.g., PPS and PEEK) in the thickness directions (up-and-down directions). The first ring 11 and the second ring 12 correspond to the upper layer and the lower layer, respectively.

The first ring 11 is formed, as shown in FIG. 3, with a plurality of screw holes 11b in an upper surface 11a for attaching the retainer ring 8 to the holding head 4, and a pressed-and-fitted portion 11d having a concave shape in section in the thickness directions (vertical directions) and a ring shape (concentric shape with the first ring 11) over the full circumference in a lower surface 11c (lower part). The pressed-and-fitted portion 11d shaped like a dovetail groove is formed in such a way that an opening thereof widens from the lower surface 11c toward the upper surface 11a along inclination portions 11e symmetrical with respect to a center line L1 of the pressed-and-fitted portion 11d. The end part of each inclination portion 11e on the side of the upper surface 11a is formed with an inside-R 11f, and the end part thereof on the side of the lower surface 11c is formed with an outside-R 11g for inserting (pressing) a pressing-and-fitting portion 12d (described later) more easily into the pressed-and-fitted portion 11d. The inclination of each inclination portion 11e is set at an angle as great as possible within a range where the pressing-and-fitting portion 12d can be inserted (pressed) into the pressed-and-fitted portion 11d, thereby fitting (engaging) inclination portions 12e (described later) more securely with the inclination portions 11e.

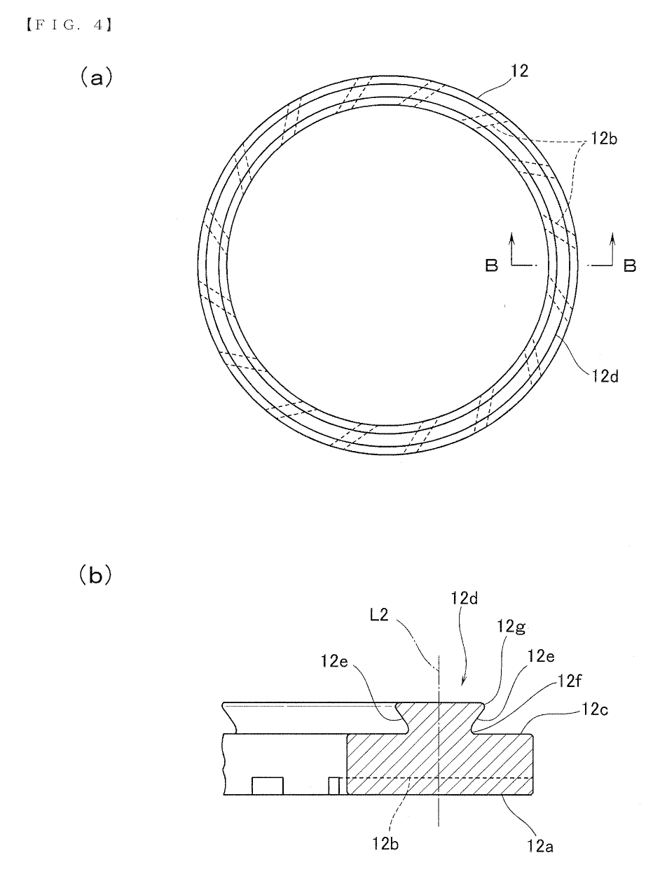

The second ring 12 has inside and outside diameters substantially equal to those of the first ring 11. A pressure surface 12a (lower surface) thereof for pressing the polish surface 3a of the polish pad 3 is formed, as shown in FIG. 4, with a plurality of groovy slits 12b for clearing (discharging) polish chips. Further, the second ring 12 is formed with the pressing-and-fitting portion 12d having a convex shape in section in the thickness directions (vertical directions) and a ring shape (concentric shape with the second ring 12) over the full circumference in an upper surface 12c (upper part). The pressing-and-fitting portion 12d shaped like a dovetail groove is formed in such a way that an opening thereof widens upward from the upper surface 12c along the inclination portions 12e symmetrical with respect to a center line L2 of the pressing-and-fitting portion 12d. The base part of each inclination portion 12e is formed with an inside-R 12f, and the front end part thereof is formed with an outside-R 12g for inserting (pressing) the pressing-and-fitting portion 12d more easily into the pressed-and-fitted portion 11d. The inclination portions 12e incline at an angle substantially equal to the inclination portions 11e of the pressed-and-fitted portion 11d and have a mutual interval (distance) slightly longer than the interval between the inclination portions 11e of the pressed-and-fitted portion 11d. This makes it possible to press (insert while applying a horizontal compressive force) the pressing-and-fitting portion 12d into the pressed-and-fitted portion 11d and fit the inclination portions 12e to the inclination portions 11e.

As described so far, the pressed-and-fitted portion 11d of the first ring 11 constitutes the pressed portion and the fitted portion and the pressing-and-fitting portion 12d of the second ring 12 constitutes the pressing portion and the fitting portion. Further, the pressed-and-fitted portion 11d of the first ring 11 and the pressing-and-fitting portion 12d of the second ring 12 constitutes the pressing-in means and the fitting means.

The first ring 11 and the second ring 12 are united (joined) into the retainer ring 8 by the method of applying an adhesive 13 (bonding agent) to the lower surface 11c of the first ring 11 and the upper surface 12c of the second ring 12, placing the first ring 11 on top of the second ring 12 by positioning the pressed-and-fitted portion 11d to the pressing-and-fitting portion 12d, and as shown in FIG. 5, pressing and fitting the pressing-and-fitting portion 12d into the pressed-and-fitted portion 11d by pushing (pressing) the first ring 11 onto the second ring 12. This brings the adhesive 13 between (to the joint part of) the lower surface 11c of the first ring 11 and the upper surface 12c of the second ring 12. Some of the adhesive 13 pouring out of the inside and outside edges of the first ring 11 and the second ring 12 is removed after hardening.

In the retainer ring 8 described so far, the first ring 11 and the second ring 12 are united by pressing and fitting the pressing-and-fitting portion 12d into the pressed-and-fitted portion 11d, thereby keeping them more securely united. In the pressing-in and fitting unification, different from bolting unification, a vibration, a repeated stress or the like given to the retainer ring 8 by polishing the wafer W is prevented from loosening the press-in or fitting state, thereby keeping the first ring 11 and the second ring 12 more securely united. Besides, pressing and fitting the pressing-and-fitting portion 12d into the pressed-and-fitted portion 11d facilitates a good (full) transmission of a shearing stress or the like given to the retainer ring 8 (the second ring 12) by polishing the wafer W to the first ring 11 and further the holding head 4 via the pressing-and-fitting portion 12d and the pressed-and-fitted portion 11d. This prevents the first ring 11 and the second ring 12 from peeling off, different from adhesive unification. In addition, slurry, polish chips or the like is hindered from coming into the part (press-in or fitting part) leaving no space between the pressing-and-fitting portion 12d and the pressed-and-fitted portion 11d. Even if it comes accidentally into there, then different from adhesive unification, slurry, polish chips or the like will not loosen the press-in or fitting to thereby keep the retainer ring 8 more securely united. This secure unification maintenance of the retainer ring 8 (firm unification of the first ring 11 and the second ring 12) maintains the flatness of the retainer ring 8 (the second ring 12) to thereby unify the pressing force against the polish pad 3 of the retainer ring 8 and keep the uniformity unchanged.

Furthermore, the pressed-and-fitted portion 11d and the pressing-and-fitting portion 12d are formed over the full circumference of the retainer ring 8, thereby realizing a press-in and a fitting of the pressed-and-fitted portion 11d and the pressing-and-fitting portion 12d over the full circumference of the retainer ring 8, and thus, keeping the retainer ring 8 still more securely united. Besides, the formation of the pressed-and-fitted portion 11d and the pressing-and-fitting portion 12d over the full circumference of the retainer ring 8 unifies the shape (sectional shape) or unification state (press-in and fitting state) of the retainer ring 8 over the whole circumference, thereby making uniform the pressing force against the polish pad, different from bolting unification provided with a plurality of holes.

Moreover, the adhesive 13 is provided between the lower surface 11c of the first ring 11 and the upper surface 12c of the second ring 12, thereby keeping the first ring 11 and the second ring 12 more securely united. Besides, the bonding agent prevents slurry, polish chips or the like from coming between (into the joint part of) the first ring 11 and the second ring 12, thereby further stabilizing the united retainer ring 8.

In addition, the stainless-steel first ring 11 and the super-engineering plastic second ring 12 are united by the pressing-in and the fitting, thereby preventing some difference in material, strength or the like between the first ring 11 and the second ring 12 from deforming or distorting them, so that the two rings 11 and 12 can be well united. Besides, different from bolting unification, there is no need to form a plurality of bolt insertion holes in the first ring 11 and a plurality of screw holes in the second ring 12, thereby not only reducing the machining process hour, but also increasing the polish allowance (polish length in the thickness directions) of the second ring 12, so that the second ring 12 can be fully effectively utilized.

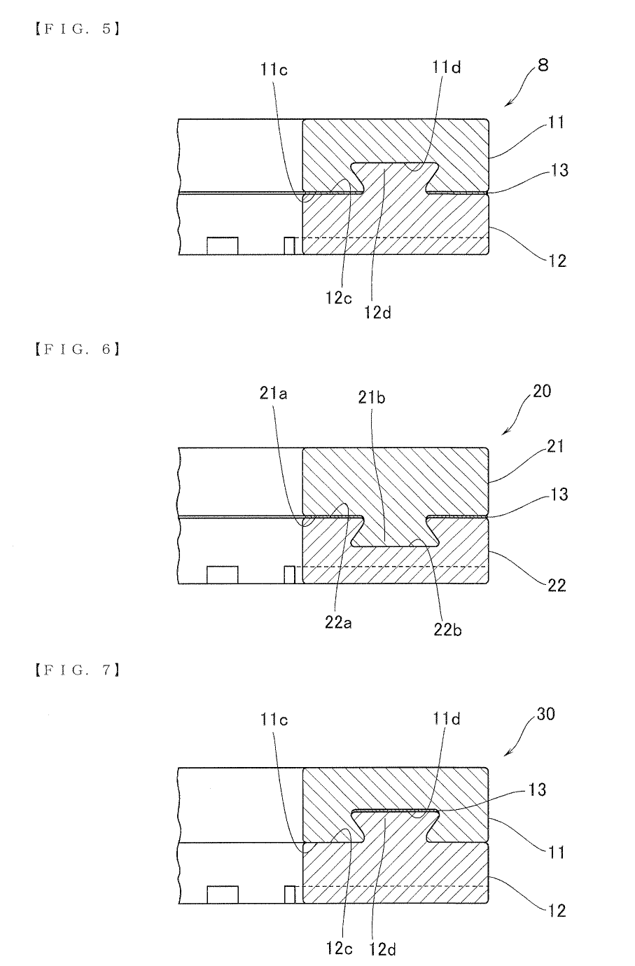

In this embodiment, the first ring 11 and the second ring 12 are provided with the pressed-and-fitted portion 11d and the pressing-and-fitting portion 12d, respectively, and the adhesive 13 is provided between the lower surface 11c of the first ring 11 and the upper surface 12c of the second ring 12. However, the configurations shown in FIGS. 6 to 10 can also keep the first ring 11 and the second ring 12 more securely united.

In a second retainer ring 20 shown in FIG. 6, a first ring 21 is formed with a pressing-and-fitting portion 21b over the full circumference in a lower surface 21a (lower part) and a second ring 22 is formed with a pressed-and-fitted portion 22b over the full circumference in an upper surface 22a (upper part). The pressing-and-fitting portion 21b is pressed and fitted into the pressed-and-fitted portion 22b, and the adhesive 13 lies between (at the joint part of) the lower surface 21a of the first ring 21 and the upper surface 22a of the second ring 22.

In a third retainer ring 30 shown in FIG. 7, in the same way as the above retainer ring 8, the first ring 11 is formed with the pressed-and-fitted portion 11d over the full circumference in the lower surface 11c (lower part) and the second ring 12 is formed with the pressing-and-fitting portion 12d over the full circumference in the upper surface 12c (upper part). The pressing-and-fitting portion 12d is pressed and fitted into the pressed-and-fitted portion 11d, and the adhesive 13 lies between (at the joint part of) the bottom surface of the pressed-and-fitted portion 11d and the front-end surface of the pressing-and-fitting portion 12d.

In a fourth retainer ring 40 shown in FIG. 8, similarly to the retainer ring 20, the first ring 21 is formed with the pressing-and-fitting portion 21b over the full circumference in the lower surface 21a (lower part) and the second ring 22 is formed with the pressed-and-fitted portion 22b over the full circumference in the upper surface 22a (upper part). The pressing-and-fitting portion 21b is pressed and fitted into the pressed-and-fitted portion 22b, and the adhesive 13 lies between (at the joint part of) the front-end surface of the pressing-and-fitting portion 21b and the bottom surface of the pressed-and-fitted portion 22b.

In a fifth retainer ring 50 shown in FIG. 9, in the same way as the retainer rings 8 and 30, the first ring 11 is formed with the pressed-and-fitted portion 11d over the full circumference in the lower surface 11c (lower part) and the second ring 12 is formed with the pressing-and-fitting portion 12d over the full circumference in the upper surface 12c (upper part). The pressing-and-fitting portion 12d is pressed and fitted into the pressed-and-fitted portion 11d, and the adhesive 13 lies with no space at all the joint parts of the first ring 11 and the second ring 12: between the lower surface 11c of the first ring 11 and the upper surface 12c of the second ring 12, between the bottom surface of the pressed-and-fitted portion 11d and the front-end surface of the pressing-and-fitting portion 12d, between the inclination portion 11e and the inclination portions 12e and at the rest.

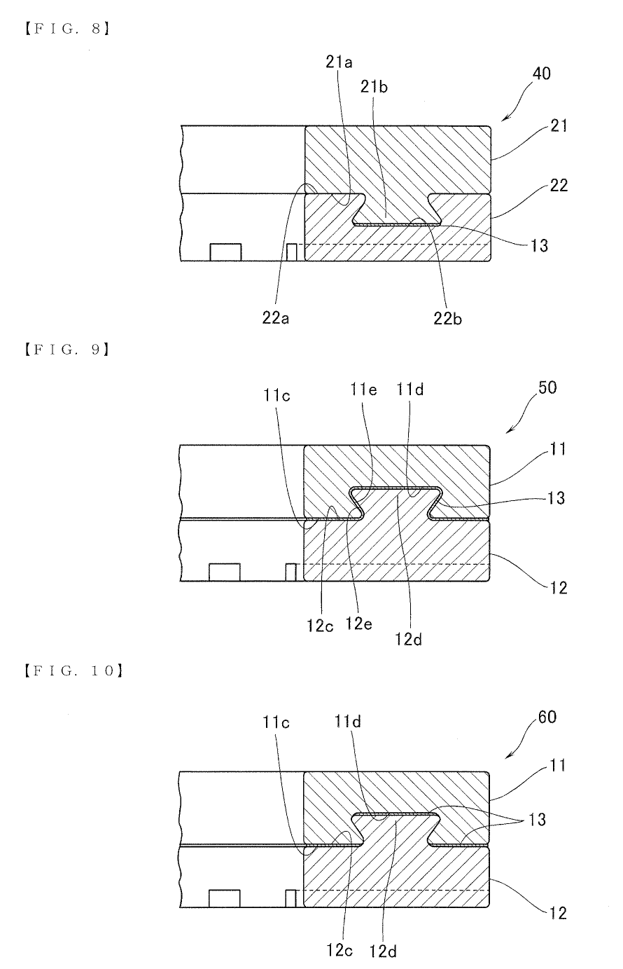

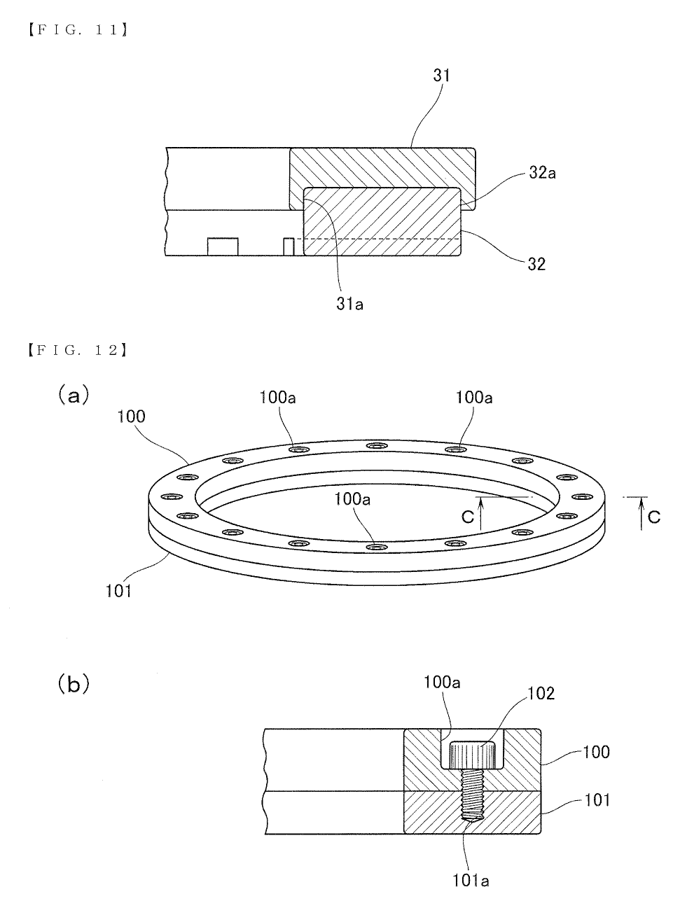

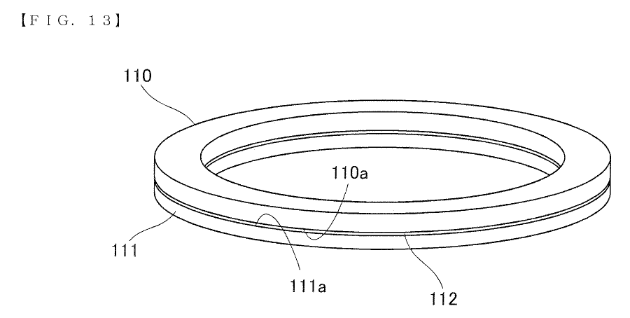

In a sixth retainer ring 60 shown in FIG. 10, similarly to the retainer rings 8, 30 and 50, the first ring 11 is formed with the pressed-and-fitted portion 11d over the full circumference in the lower surface 11c (lower part) and the second ring 12 is formed with the pressing-and-fitting portion 12d over the full circumference in the upper surface 12c (upper part). The pressing-and-fitting portion 12d is pressed and fitted into the pressed-and-fitted portion 11d, and the adhesive 13 lies between the lower surface 11c of the first ring 11 and the upper surface 12c of the second ring 12 and between the bottom surface of the pressed-and-fitted portion 11d and the front-end surface of the pressing-and-fitting portion 12d.

In the retainer rings 20 and 40 where the first ring 21 is formed with the pressing-and-fitting portion 21b and the second ring 22 is formed with the pressed-and-fitted portion 22b, the adhesive 13 may be provided at some joint parts of the first ring 21 and the second ring 22, as is the case with the retainer rings 50 and 60.

The embodiment of the present invention has been described so far, however, a specific configuration is not limited to this embodiment. Hence, the present invention includes numerous variations in design and the like without departing from the scope of the present invention. For example, in this embodiment, the pressing-and-fitting portion 12d is pressed and fitted into the pressed-and-fitted portion 11d over the full circumference of the retainer ring 8. However, it may be partly pressed and fitted, for example, a discontinuous (OR non-ring shaped) pressing-and-fitting portion formed in the upper surface 12c of the second ring 12 may be pressed and fitted partly into the pressed-and-fitted portion 11d of the first ring 11.

Furthermore, in this embodiment, the pressed-and-fitted portion 11d of the first ring 11 and the pressing-and-fitting portion 12d of the second ring 12 constitutes the pressing-in means and the fitting means, and the first ring 11 and the second ring 12 are united by pressing-in and fitting, however, the first ring 11 and the second ring 12 may be united by either pressing-in (the pressing-in means) or fitting (the fitting means). For example, the first ring 11 and the second ring 12 may be united only by pressing a pressing-and-fitting portion having no such inclination portion 12e as described above (e.g., having a straight or taper shape) into a pressed-and-fitted portion having a shape and a size for fitting with this pressing-and-fitting portion. Moreover, as shown in FIG. 11, a first ring 31 and a second ring 32 may be united only by pressing a concave portion 31a (the pressed-and-fitted portion) having a concave shape in section at a lower part of the first ring 31 into an upper part 32a (the pressing-and-fitting portion) of the second ring 32.

In addition, in this embodiment, the adhesive 13 is provided in the joint part of the first ring 11 and the second ring 12, however, it may be omitted. The decision whether the adhesive 13 should be provided can be made according to the degree to which the pressing-and-fitting portion 12d is pressed and fitted into the pressed-and-fitted portion 11d, the greatness of a shearing stress applied to the retainer ring 8, the extent to which slurry, polish chips or the like comes into there, or another factor. Besides, the first ring is made of stainless steel and the second ring 12 is made of super-engineering plastic. As a matter of course, however, the first ring 11 may be made of a material such as another kind of metal and ceramics and the second ring 12 may be made of a material such as ceramics.

### DESCRIPTION OF THE SYMBOLS

1: CMP apparatus
2: base
3: polish pad
3a: polish surface
4: holding head
5: slurry supply nozzle
5a: slurry
6: dresser
7: head body
8: retainer ring
9: elastic film
11: first ring
11c: lower surface (lower part)
11d: pressed-and-fitted portion (pressed portion, fitted portion)
12: second ring
12c: upper surface (upper part)
12d: pressing-and-fitting portion (pressing portion, fitting portion)
13: adhesive (bonding agent)
W: wafer
W1: polished surface

1. A retainer ring which has a two-layer structure of a first ring and a second ring in a holding head of a CMP apparatus,
characterized in that the first ring and the second ring are united by at least either of a pressing-in means and a fitting means.

2. The retainer ring according to claim 1, characterized in that the pressing-in means includes a pressing portion formed in a lower part of the first ring and a pressed portion to be pressed by the pressing portion formed in an upper part of the second ring.

3. The retainer ring according to claim 2, characterized in that the pressing portion is formed over the full circumference in a lower part of the first ring, and the pressed portion is formed over the full circumference in an upper part of the second ring.

4. The retainer ring according to claim 1, characterized in that the pressing-in means includes a pressed portion formed in a lower part of the first ring and a pressing portion to press the pressed portion formed in an upper part of the second ring.

5. The retainer ring according to claim 4, characterized in that the pressed portion is formed over the full circumference in a lower part of the first ring, and the pressing portion is formed over the full circumference in an upper part of the second ring.

6. The retainer ring according to claim 1, characterized in that the fitting means includes a fitting portion formed in a lower part of the first ring and a fitted portion to be fitted by the fitting portion formed in an upper part of the second ring.

7. The retainer ring according to claim 6, characterized in that the fitting portion is formed over the full circumference in a lower part of the first ring, and the fitted portion is formed over the full circumference in an upper part of the second ring.

8. The retainer ring according to claim 1, characterized in that the fitting means includes a fitted portion formed in a lower part of the first ring and a fitting portion to fit the fitted portion formed in an upper part of the second ring.

9. The retainer ring according to claim 8, characterized in that the fitted portion is formed over the full circumference in a lower part of the first ring, and the fitting portion is formed over the full circumference in an upper part of the second ring.

10. The retainer ring according to claim 1, characterized in that a bonding agent is provided between the first ring and the second ring.

11. The retainer ring according to claim 1, characterized in that the first ring is metallic and the second ring is super-engineering plastic.
